(19) United States
(12) Patent Application Publication
(10) Pub. No.: US 2026/0255886 A1
(43) Pub. Date: Aug. 27, 2026

(54) DUAL-DIMENSIONAL MEMORY JUNCTION DEVICE AND PREPARATION METHOD, PERFORMANCE ACQUISITION METHOD, AND APPLICATION METHOD FOR DUAL-DIMENSIONAL MEMORY JUNCTION DEVICE

(71) Applicant: HUAZHONG UNIVERSITY OF SCIENCE AND TECHNOLOGY, Hubei (CN)

(72) Inventors: Xiaomin CHENG, Hubei (CN); Yunhao LUO, Hubei (CN); Chunhui WU, Hubei (CN); Lijuan CAO, Hubei (CN); Xiangshui MIAO, Hubei (CN)

(73) Assignee: HUAZHONG UNIVERSITY OF SCIENCE AND TECHNOLOGY, Hubei (CN)

(21) Appl. No.: 19/406,828

(22) Filed: Dec. 2, 2025

Related U.S. Application Data
(63) Continuation of application No. PCT/CN2025/083692, filed on Mar. 20, 2025.

(30) Foreign Application Priority Data
Feb. 25, 2025 (CN) 202510209204.4

(51) Int. Cl. H10N 70/20; H10B 63/00; H10N 70/00

(52) U.S. Cl. CPC H10N 70/257; H10B 63/80; H10N 70/023; H10N 70/026; H10N 70/25; H10N 70/8833; H10N 70/884

(57) ABSTRACT

The disclosure pertains to the field of semiconductor optoelectronic devices and micro-nanoelectronics, specifically disclosing a dual-dimensional memory junction device, along with a preparation method, a performance acquisition method, and an application method thereof. The dual-dimensional memory junction device includes a first contact electrode, a doped n-type Si layer, an AgOₓ charge trapping layer, and a second contact electrode. The AgOₓ charge trapping layer is combined with the doped n-type Si layer to form a heterojunction transition region.

### CROSS-REFERENCE TO RELATED APPLICATION

The present application is a continuation of PCT application serial No. PCT/CN2025/083692, filed on March 20, 2025, which claims the priority benefit of China application no. 202510209204.4, filed on February 25, 2025. The entirety of each of the above mentioned patent applications is incorporated by reference herein and made a part of this specification.

### BACKGROUND

### Technical Field

This disclosure belongs to the field of semiconductor optoelectronic devices and micro-nano electronics, and more specifically, relates to a dual-dimensional memory junction device and a preparation method, a performance acquisition preparation, and an application method for the dual-dimensional memory junction device.

### Description of Related Art

With the advent of artificial intelligence, various types of systems that mimic human visual and neuromorphic systems have continuously been provided to achieve genuine autonomous driving by replacing human capabilities. However, the development of this technology is significantly constrained in terms of architecture, hardware, and integration. Conventional machine vision systems typically employ charge-coupled devices (CCD) for image sensing and use complementary metal-oxide-semiconductor (CMOS)-based computing and storage chips for further storage and processing of sensory information. This architecture results in the separation of sensing, computing, and storage units. Edge-computing-based autonomous driving imposes stringent limits on hardware comprehensive overhead, thereby constraining development in speed, energy efficiency, and integration due to system architecture and hardware limitations. Therefore, the integration of sensing, storage, and computing units from an architectural perspective, and the realization of multidimensional information processing from optical to electrical on a hardware level, are essential to achieving the most efficient and compact machine vision systems.

On this basis, the concept of in-sensor computing and its related devices has been proposed. Currently, the most outstanding in terms of performance and the most feasible in practical applications is the split-gate homojunction transistor based on electrostatic doping. This technology utilizes the photovoltaic effect for computation, enabling self-powered image processing while also being capable of handling a wide range of dynamic and static optical information processing, and is widely recognized as the mainstream technology in this field. However, this technical solution presents two major drawbacks: First, the four-terminal structure of the source, drain, and split-gate in a split-gate homojunction transistor based on electrostatic doping results in an exponential increase in the complexity of circuit interconnections during integration, rendering it unsuitable for large-scale integration. Second, this technical solution is limited to computations in the photovoltaic dimension and cannot further process subsequent deep neural network operations based on electrical signal dimensions. Therefore, developing a fewer-terminal, multi-dimensional memory junction device is crucial for achieving a compact and efficient machine vision system.

### SUMMARY

In light of the deficiencies present in existing technologies, the purpose of the present disclosure is to provide a dual-dimensional memory junction device and a preparation method, a performance acquisition preparation, and an application method for the dual-dimensional memory junction device. The present disclosure aims to address the issue where the four-terminal structure of source, drain, and split gate in homojunction transistors based on electrostatic doping results in an exponential increase in interconnection complexity during integration, rendering it unsuitable for large-scale integration. Additionally, the present disclosure seeks to overcome the limitation of being restricted to photovoltaic dimensional computation, which is inadequate for handling deep neural network processing based on electrical signal dimensions.

To achieve the above purpose, in a first aspect, the present disclosure provides a dual- dimensional memory junction device, including a first contact electrode, a doped n-type Si layer, an AgOₓ charge trapping layer, and a second contact electrode stacked sequentially from bottom to top; wherein, 0.4<x<1.2.

The doped n-type Si layer has a Fermi energy level lower than a bandgap midline energy level thereof. The AgOₓ charge trapping layer is combined with the doped n-type Si layer to form a heterojunction transition region. An area of the AgOₓ charge trapping layer is larger than an area of the second contact electrode.

The first contact electrode and the second contact electrode are provided for providing ohmic contact and voltage driving.

The heterojunction transition region is configured for trap ionization and deionization transitions based on the AgOₓ charge trapping layer. Under voltage drive, continuous adjustability and mutual coupling of memory intensity are achieved in the two dimensions of photovoltaic responsivity and electrical conductivity, with non-volatility.

Further preferably, the first contact electrode is Al, Ti, Al silicide, or Ti silicide; the second contact electrode is Au or Pt.

Further preferably, a doping impurity in the doped n-type Si layer is a combination of one or more materials. The doped n-type Si layer is P-doped, and the order of magnitude of the doping concentration is 1E15cm⁻³.

Further preferably, a thickness of the first contact electrode is 3nm-200nm; a thickness of the doped n-type Si layer is 30nm-500μm; a thickness of the AgOₓ charge trapping layer is 10nm-100nm; and a thickness of the second contact electrode is 3nm-200nm.

In a second aspect, based on the dual-dimensional memory junction device, the present disclosure provides a corresponding performance acquisition method, which is specifically as follows.

After applying a negative voltage on the second contact electrode of the dual-dimensional memory junction device, a forward voltage is adopted to read a resistance state of the dual-dimensional memory junction device under unilluminated conditions, and the decrease of the resistance state of the dual-dimensional memory junction device is acquired. Meanwhile, based on a 0V short-circuit state, a short-circuit current of the dual-dimensional memory junction device is read under illuminated conditions, and the increase of a photovoltaic responsivity of the dual-dimensional memory junction device is acquired.

After applying the forward voltage on the second contact electrode of the dual-dimensional memory junction device, the forward voltage is adopted to read the resistance state of the dual-dimensional memory junction device under unilluminated conditions, and the increase of the resistance state of the dual-dimensional memory junction device is acquired. Meanwhile, based on the 0V short-circuit state, the short-circuit current of the dual-dimensional memory junction device is read under illuminated conditions, and the decrease of the photovoltaic responsivity of the dual-dimensional memory junction device is acquired.

Further preferably, with the increase of the thickness of the AgOₓ charge trapping layer, the amplitude of the forward voltage adopted for reading the resistance state of the dual-dimensional memory junction device is also increased.

Furthermore, when the thickness of the AgOₓ charge trapping layer is 23nm, the forward voltage adopted for reading the resistance state of the dual-dimensional memory junction device is a forward voltage less than or equal to 0.4V.

In a third aspect, based on the dual-dimensional memory junction device, the present disclosure provides a corresponding neural network application method, specifically including the following steps.

The first contact electrode and the second contact electrode of the dual-dimensional memory junction device serve as word lines and bit lines respectively, thereby achieving integration in a crossbar array configuration.

One of the crossbar arrays is used as a photovoltaic response dimension array to map all pixels of an input optical image in array form in the photovoltaic response dimension array, so that a Hadamard product operation is performed between an optical image and a photovoltaic response matrix corresponding to the photovoltaic response dimension array, and a current vector is output.

Another one of the crossbar arrays is used as a conductivity dimension array to convert the output current vector to a voltage vector for input to the conductivity dimension array, thereby completing a matrix-vector multiplication through Kirchhoff's current law and Ohm's law, and outputting a classification task of the optical image.

In a fourth aspect, the present disclosure provides a method for preparing a dual-dimensional memory junction device, specifically including the following steps.

Step 1: A doped n-type Si layer is prepared by doping a molten material during the growth of monocrystalline Si using a Czochralski method or a float zone method. Alternatively, an intrinsic Si layer is grown using either the Czochralski method or the float zone method, and then the doped n-type Si layer is prepared through thermal diffusion doping or ion implantation methods.

Step 2: At least one of the following methods—sputtering, physical vapor deposition, or chemical vapor deposition—is adopted to prepare the first contact electrode on a rear side of the doped n-type Si layer.

Step 3: A masking layer for the AgOₓ charge trapping layer is prepared on the doped n-type Si layer through patterning, and then the AgOₓ charge trapping layer is prepared. Subsequently, the masking layer is removed.

Step 4: A patterned masking layer for the second contact electrode is prepared above the AgOₓ charge trapping layer, and then the second contact electrode is prepared. The masking layer is removed to complete the preparation of the dual-dimensional memory junction device.

Further preferably, the preparation processes for the second contact electrode, the AgOₓ charge trapping layer, and the first contact electrode may be one of the following: sputtering, physical vapor deposition, chemical vapor deposition, molecular beam epitaxy, atomic layer deposition, pulsed laser deposition, or electrochemical methods.

Overall, the technical solution conceived through the present disclosure presents the following advantageous effects compared to existing technologies.

The present disclosure provides the dual-dimensional memory junction device, including the first contact electrode, the n-type doped Si layer, the AgOₓ charge trapping layer, and the second contact electrode, which are sequentially stacked from bottom to top. The charge trapping layer is combined with the doped n-type Si layer to form the heterojunction transition region. Within the AgOₓ charge trapping layer, 0.4 < x < 1.2. The area of the charge trapping layer should be greater than that of the second contact electrode to enable photo-sensing. The present disclosure allows for the memory of information in two distinct dimensions: photovoltaic and conductivity, differing from existing devices that can only achieve single-dimensional memory functionality.

The present disclosure presents a method based on the dual-dimensional memory junction device. Leveraging the inherent self-rectifying characteristics of the device as a PN junction, the integration of the device into the crossbar array does not require additional gating devices. Moreover, the present disclosure features the theoretically minimal requirement of two terminals, which is advantageous for large-scale integration.

The present disclosure presents an application based on the dual-dimensional memory junction device, utilizing two dimensions of the device to construct a photovoltaic dimension array and a conductivity dimension array. The photovoltaic dimension array executes the Hadamard product of the optical matrix and the electrical matrix, outputting an electrical signal in vector form. The vector is then input into the conductivity dimension matrix to accomplish matrix-vector multiplication, thereby performing image information classification tasks. The dual-dimensional arrays constructed from a single device enable the development of a compact and efficient machine vision system.

### BRIEF DESCRIPTION OF THE DRAWINGS

FIG. 1 is a structural schematic diagram of a dual-dimensional memory junction device provided by an embodiment of the present disclosure.

FIG. 2A illustrates a diagram showing a direct current (DC) scanning performance of an electrical conductivity in a Ti/n-Si/p-AgOₓ/Pt dual-dimensional memory junction device provided in embodiments of the present disclosure, specifically under unilluminated conditions.

FIG. 2B illustrates a diagram showing a DC scanning performance of the electrical conductivity in the Ti/n-Si/p-AgOₓ/Pt dual-dimensional memory junction device provided in embodiments of the present disclosure, specifically under illuminated conditions.

FIG. 3A is a diagram illustrating a photovoltaic weight pulse plasticity performance of the Ti/n-Si/p-AgOₓ/Pt dual-dimensional memory junction device provided in embodiments of the present disclosure.

FIG. 3B is a diagram illustrating a conductivity weight pulse plasticity performance of the Ti/n-Si/p-AgOₓ/Pt dual-dimensional memory junction device provided in embodiments of the present disclosure.

FIG. 4A illustrates a 1000-second long-term retention diagram of a light-responsive state of the Ti/n-Si/p-AgOₓ/Pt dual-dimensional memory junction device provided in embodiments of the present disclosure.

FIG. 4B illustrates a 1000-second long-term retention diagram of a multi-conductivity in the Ti/n-Si/p-AgOₓ/Pt dual-dimensional memory junction device provided in embodiments of the present disclosure.

FIG. 5A illustrates a circuit connection architecture of two crossbar arrays provided in embodiments of the present disclosure.

FIG. 5B illustrates a computational diagram of a network architecture corresponding to the circuit architecture provided in embodiments of the present disclosure.

FIG. 5C illustrates a diagram showing a performance of a classification task for the letters 'H', 'U', 'S', and 'T' as provided in embodiments of the present disclosure.

FIG. 5D illustrates a diagram showing a trend of accuracy and loss function variations over iterations in the classification task provided in embodiments of the present disclosure.

### DESCRIPTION OF THE EMBODIMENTS

In order to elucidate the objectives, technical solutions, and advantages of the present disclosure more clearly, the present disclosure is further detailed in conjunction with the accompanying drawings and embodiments. It should be understood that the specific embodiments described herein are solely for the purpose of explaining the present disclosure and are not intended to limit it.

In the present disclosure, the term "and/or" is used to describe the relational connection between associated objects, indicating that there can be three types of relationships. For instance, A and/or B can represent: the presence of A alone, the simultaneous presence of both A and B, or the presence of B alone. In this document, the symbol "/" signifies an "or" relationship between associated objects; for example, A/B indicates either A or B.

The terms "first" and "second," etc., as used in the specification and claims of the present disclosure, are employed to distinguish between different objects and are not used to describe a specific order of the objects.

In the embodiments of the present disclosure, the terms "exemplary" or "for example" are utilized to indicate an instance, illustration, or explanation. Any embodiment or design scheme described in the embodiments of the present disclosure as "exemplary" or "for example" should not be construed as being preferred or more advantageous over other embodiments or design schemes. Specifically, the use of the terms "exemplary" or "for example" is intended to present the relevant concepts in a concrete manner.

In the description of embodiments of the present disclosure, unless otherwise specified, the term "multiple" shall mean two or more.

Below, the embodiments of the present disclosure will be described in conjunction with the accompanying drawings.

In a first aspect, the present disclosure provides a dual-dimensional memory junction device, including a first contact electrode, an n-type doped Si layer, an AgOₓ charge trapping layer, and a second contact electrode, which are sequentially stacked from bottom to top. The charge trapping layer is combined with the doped n-type Si layer to form a heterojunction transition region. Within the AgOₓ charge trapping layer, 0.4 < x < 1.2. An area of the AgOₓ charge trapping layer should be greater than that of the second contact electrode to enable photo-sensing. The present disclosure is based on the transition of trap ionization and deionization in the AgOₓ charge trapping layer. The integrated effect transition induces a significant variation in the intensity of the memory junction device across two dimensions: photovoltaic responsivity and electrical conductivity. Benefiting from the continuity of the trap ionization process, the memory intensity of the memory junction device in terms of photovoltaic responsivity and conductivity is continuously adjustable, mutually coupled, and non-volatile.

Further preferably, a doping impurity of the doped Si layer is a combination of one or more materials that form n-type Si, and a Fermi level of the doped n-type Si layer should be lower than a bandgap midline energy level thereof. The n-type Si layer is p-doped, with a doping concentration around 1E15cm⁻³, which may fluctuate within two orders of magnitude. The position of the Fermi level resulting from the doping concentration, combined with the final energy band structure of the device, results in optimal performance, balancing the transition performance in two dimensions.

Further preferably, the first contact electrode may be composed of Al, Ti, aluminum silicide, or titanium silicide. When the first contact electrode is made of Al or Ti, annealing is performed after growth to form a metal silicide, achieving an optimal ohmic conductivity. The second contact electrode may be composed of Au or Pt, which possesses a high work function and exhibits inertness, making it suitable for forming ohmic contact with p-AgOₓ.

Further preferably, a thickness of the first contact electrode is 3nm-200nm; a thickness of the doped n-type Si layer is 30nm-500μm; a thickness of the AgOₓ charge trapping layer is 10nm-100nm; and a thickness of the second contact electrode is 3nm-200nm.

In a second aspect, based on the dual-dimension memory junction device provided above, the present disclosure provides a corresponding preparation method, which includes the following steps.

Step 1: Any smooth substrate is selected, and the first contact electrode is prepared on a surface of the substrate.

Step 2: An intrinsic Si layer is grown on the first contact electrode using one of the following methods: sputtering, physical vapor deposition, or chemical vapor deposition. Subsequently, a doped Si layer is prepared through thermal diffusion doping or ion implantation. Then Step 3 is carried out.

Steps 1 and 2 may also be performed using the following methods.

Step 1: A doped n-type Si layer is prepared by doping a molten material during the growth of monocrystalline Si using a Czochralski method or a float zone method. Alternatively, the intrinsic Si layer is grown using either the Czochralski method or the float zone method, and then the doped n-type Si layer is prepared through thermal diffusion doping or ion implantation methods.

Step 2: At least one of the following methods—sputtering, physical vapor deposition, or chemical vapor deposition—is adopted to prepare the first contact electrode on a rear side of the doped n-type Si layer.

Step 3: A masking layer for the charge trapping layer is prepared on the doped n-type Si layer through patterning.

Step 4: The charge trapping layer is prepared on the masking layer, and the masking layer is removed subsequently.

Step 5: A patterned masking layer for the second contact electrode is prepared on the charge trapping layer.

Step 6: The second contact electrode is prepared on the masking layer, and the masking layer is removed to obtain the device.

Further preferably, the preparation processes for the second contact electrode, the charge trapping layer, and the first contact electrode is selected from one of the following methods: sputtering, physical vapor deposition, chemical vapor deposition, molecular beam epitaxy, atomic layer deposition, pulsed laser deposition, or electrochemical methods.

In a third aspect, the present disclosure provides a method for obtaining the transition performance of a dual-dimensional memory junction device, which specifically includes the following steps.

A negative voltage is applied to the second contact electrode of the dual-dimensional memory junction device:

In the charge trapping layer, ionization of traps occurs, leading to a decrease in the thermal equilibrium Fermi level and an increase in hole concentration, thereby enhancing a space charge region. From an electrical perspective, a resistance state of the device is measured under dark conditions using a forward voltage less than or equal to 0.4V, resulting in a decrease in the resistance state of the device. In the photovoltaic response dimension, a short-circuit current of the device is measured under illuminated conditions in a 0V short-circuit state, resulting in an increase in the photovoltaic responsivity of the device.

Upon the application of the forward voltage to the second contact electrode of the dual-dimensional memory junction device:

In the charge trapping layer, the traps undergo deionization, resulting in an increase in the thermal equilibrium Fermi level and a decrease in hole concentration, which leads to a weakening of the space charge region. From an electrical dimension perspective, when the thickness of the AgOₓ charge trapping layer is 23nm, reading the resistance state of the device under dark conditions with the forward voltage of less than or equal to 0.4V results in an increase in the resistance state of the device. It should be noted here that as the thickness of the AgOₓ charge trapping layer increases, a larger amplitude of the forward voltage is required to read the resistance state of the dual-dimensional memory junction device. From a photovoltaic dimension perspective, reading the short-circuit current of the device under illuminated conditions with the 0V short-circuit state results in a decrease in the photovoltaic responsivity of the device.

The present disclosure provides a method for applying the dual-dimensional memory junction device, specifically including the following steps.

The first contact electrode and the second contact electrode of the device are used as the word lines and bit lines, respectively, for integration into a crossbar array.

When the array operates in a photovoltaic dimension, all pixels of an input optical image are mapped onto the array in the form of a matrix, wherein each pixel corresponds to a device. A Hadamard product of the optical responsivity matrix is then completed, resulting in the output of a current vector.

When the array operates in an electrical dimension, input voltage information is introduced into the array in the form of a vector. Each device in the array constitutes an element of a matrix. The matrix-vector multiplication is completed through the application of Kirchhoff's Current Law and Ohm's Law.

By combining the two dimensions of the crossbar array, the photovoltaic dimension array performs the Hadamard product to output a voltage vector, which is then input into the electrical dimension array to complete matrix-vector multiplication. Such approach enables the construction of a hardware system for a deep neural network in an ultra-compact manner, facilitating rapid image classification tasks from the optical dimension to the electrical dimension.

Based on the aforementioned dual-dimensional memory junction device, the present disclosure provides the corresponding preparation method, which specifically includes the following steps.

Step 1: A substrate with a crystallographic orientation of and a thickness of 500µm is selected. During the growth process via the Czochralski method, the molten material with phosphorus (P) elements is doped to obtain silicon wafers with a resistivity of 5 ohm-cm, which serves as the doped n-type Si layer. The silicon wafers are cut into samples of 1cm×1cm in size. These samples are immersed in acetone and cleaned using an ultrasonic bath for 10 minutes. Subsequently, the samples are immersed in anhydrous ethanol and ultrasonic cleaning is performed for another 10 minutes, with the ultrasonic power set at 10W for both cleaning processes. Finally, the samples are rinsed with deionized water and dried using a nitrogen gun.

Step 2: The cleaned sample is taken and a first contact electrode layer Ti in a thickness of approximately 100nm is grown on a rear side thereof using magnetron sputtering. A sputtering power is set at 200W, and an Ar atmospheric pressure is maintained at 0.5Pa, with a sputtering duration of 1000 seconds.

Step 3: The substrate is annealed at 500°C for 30 seconds to form a Ti-Si alloy, thereby achieving excellent ohmic conductivity.

Step 4: The photolithography process is employed to prepare a square photolithographic pattern on a surface of the substrate, with dimensions measuring 125μm×125μm. The sequential steps of the photolithography process are as follows: spin coating, pre-baking, pre-exposure, post-baking, post-exposure, and development.

Step 5: Magnetron sputtering is utilized to prepare an AgOₓ layer on the sample processed in Step 4. An Ag target is selected as the sputtering target, and direct current sputtering is employed. By controlling a sputtering time during the sputtering process, the thickness of the charge trapping layer may be adjusted to obtain the AgOₓ charge trapping layer. In this embodiment, O₂:Ar=20:5 is used to grow the AgOₓ layer. A thickness of the AgOₓ layer is 12 nm.

Step 6: The film sample prepared in Step 5 is immersed in acetone for 30 to 50 minutes, followed by cleansing with anhydrous ethanol and deionized water to remove a photoresist. Finally, the sample is dried using nitrogen gas.

Step 7: A square photolithographic pattern is prepared on the charge trapping layer through a lithography process, with the second contact electrode measuring 100μm×100μm. The steps of the photolithography process are, in sequence: spin coating, prebake, pre-exposure, post-exposure bake, post-exposure, and development.

Step 8: Magnetron sputtering is utilized to grow a platinum (Pt) layer with a thickness of 100nm on the sample processed in Step 7. The sputtering power is set at 100 watts, with an argon (Ar) atmosphere at a pressure of 0.5 Pa. The sputtering process is conducted for a duration of 1000 seconds, resulting in the formation of the second contact electrode.

Step 9: The film sample prepared in Step 8 is immersed in acetone for 30 minutes to 50 minutes, followed by cleaning with anhydrous ethanol and deionized water to remove the photoresist. Finally, the sample is dried using nitrogen gas.

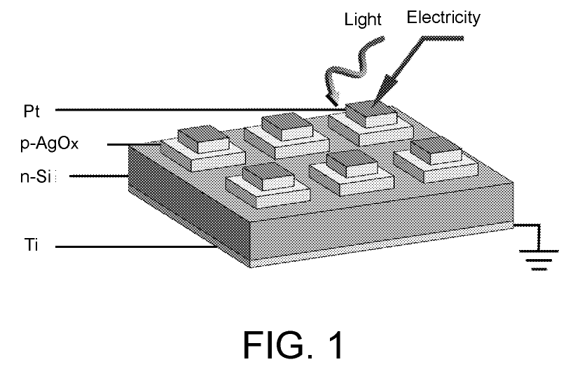

Upon completion of the aforementioned steps, a Pt/n-Si/p-AgOₓ/Pt memristor unit is prepared, with the device structure illustrated in FIG. 1.

Based on the aforementioned dual-dimensional memory junction device, the present disclosure provides a corresponding electrical characteristic testing, specifically as follows.

In the embodiments of the present disclosure, a semiconductor device analyzer is utilized to conduct direct current (DC) I/V scanning and pulse switching characteristic testing on the dual-dimensional memory junction device, with illumination provided by a Thorlabs M530F3 light source.

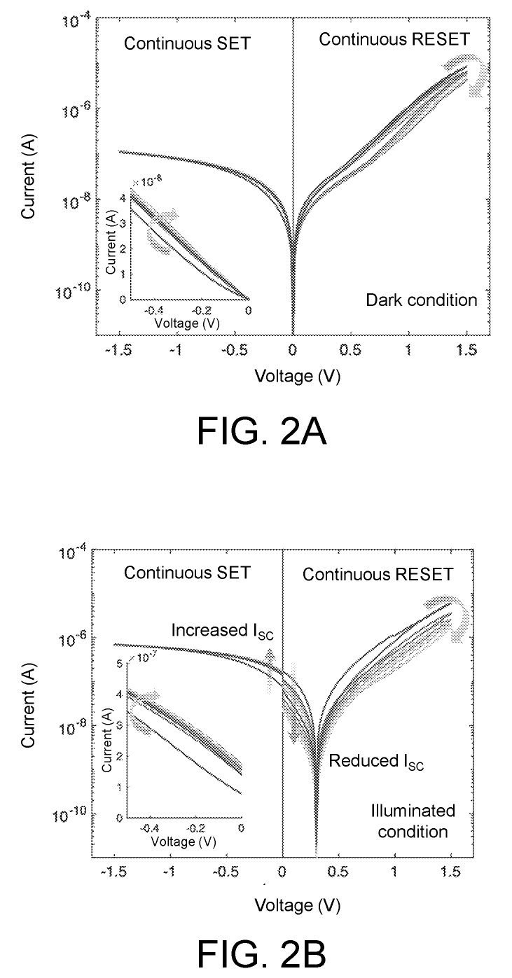

As illustrated in FIG. 2A and FIG. 2B, an electrical scanning test is conducted by applying voltage to the Pt electrode prepared in the embodiments of the present disclosure, under both dark conditions and illuminated conditions (with 530nm light at 3.1mW/cm²). This procedure results in multiple conductive states (see FIG. 2A) and photovoltaic response states (see FIG. 2B). During the scanning under dark conditions, a continuous negative voltage scanning (from 0V to -1.5V and then back to 0V) leads to a continuous increase in the current of the device, demonstrating characteristics of a continuous set (SET). Conversely, a continuous forward voltage scanning (from 0V to +5V and then back to 0V) results in a continuous decrease in the current of the device, indicating characteristics of a continuous reset (RESET). Under illuminated conditions, by observing the short-circuit current at a 0V bias, it is noted that during continuous negative voltage scanning (from 0V to -1.5V and then back to 0V), the short-circuit current continuously increases, showing characteristics of a photovoltaic response continuous set (SET). In contrast, during continuous forward voltage scanning (from 0V to +1.5V and then back to 0V), the short-circuit current continuously decreases, showing characteristics of a photovoltaic response continuous reset (RESET).

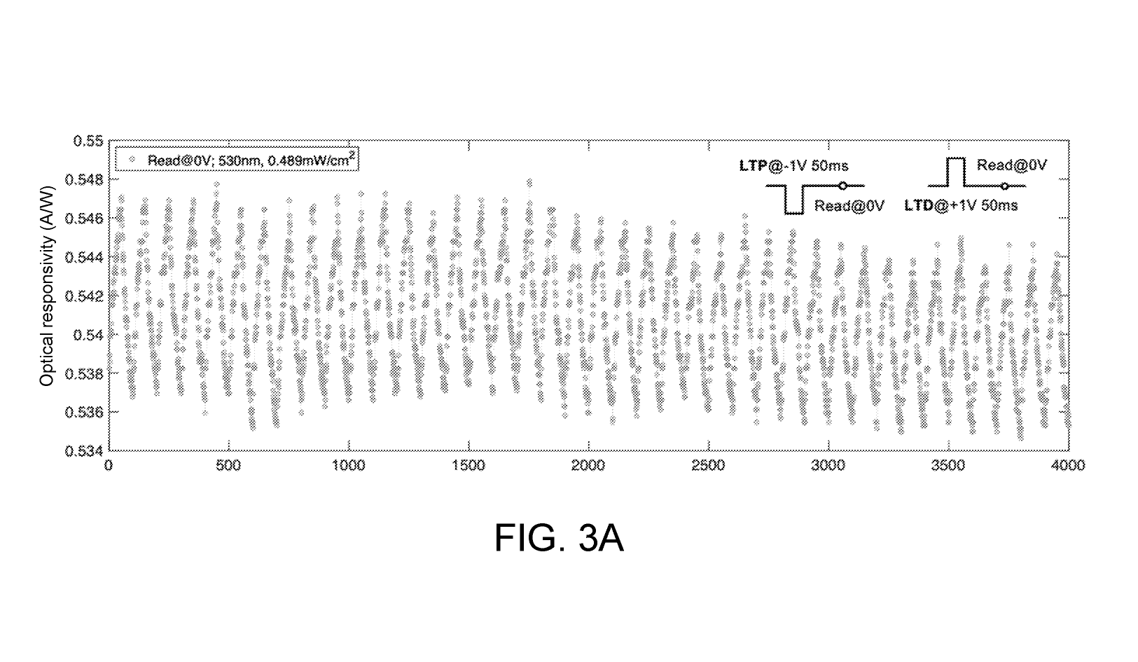

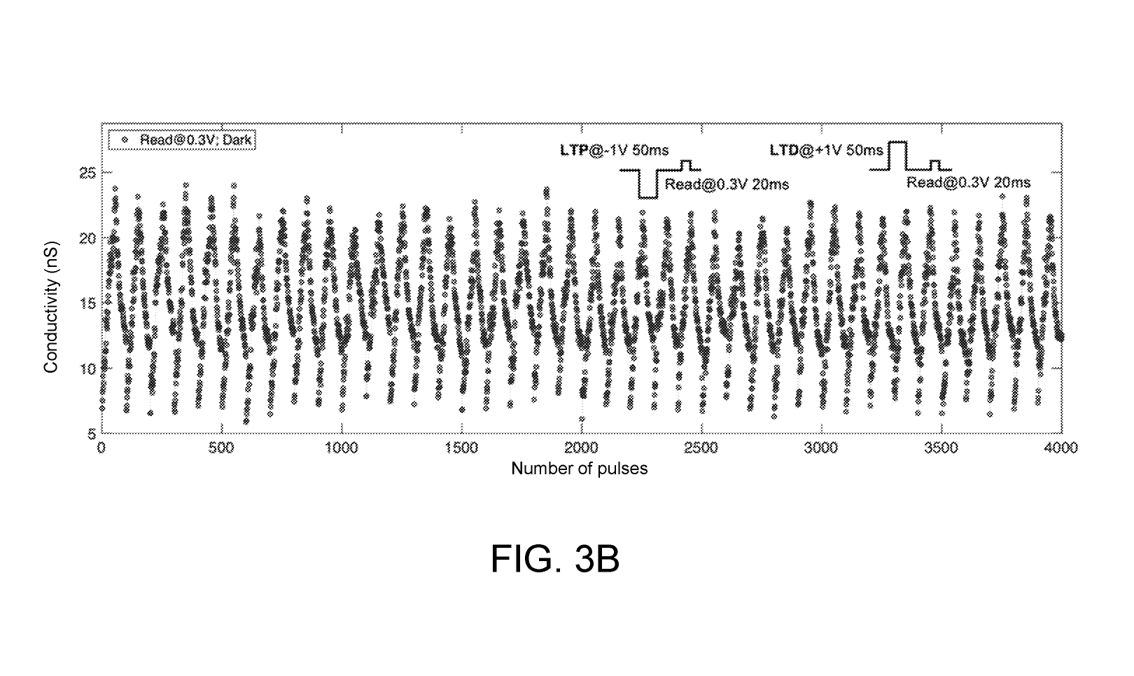

As depicted in FIG. 3A and FIG. 3B, devices prepared in accordance with the embodiments of the present disclosure are subjected to 40 cycles of Long-Term Potentiation (LTP) and Long-Term Depression (LTD) pulses applied to the Pt electrode. Each cycle consists of 50 LTP pulses and 50 LTD pulses, resulting in a total of 4000 pulses. Enhancement pulses have an amplitude of -1V and a pulse width of 50ms, while suppression pulses have an amplitude of +1V and a pulse width of 50ms. Following the conclusion of each pulse, an optical response current of the photovoltaic dimension is read in short-circuit mode under illumination at a wavelength of 530nm and a light power of 0.489mW/cm², and an optical responsivity is calculated (as shown in FIG. 3A). Additionally, the current of the electrical dimension is read in a dark condition using electrical pulses with an amplitude of 0.4V and a pulse width of 20ms, and a conductivity value is calculated (as shown in FIG. 3B).

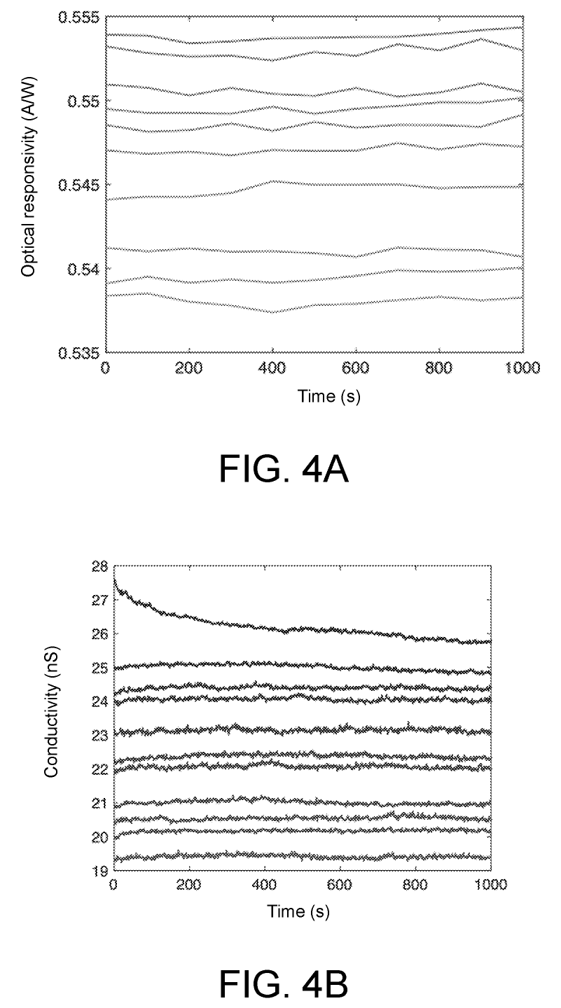

As depicted in FIG. 4A and FIG. 4B, a 1000-second retention test is conducted on the two dimensions of electrical conductivity and optical responsivity under electric and photovoltaic conditions. The illuminated condition is set at a wavelength of 530nm with a light power density of 0.15mW/cm². It is observable that there are 10 distinguishable optical responsive states and 12 distinguishable conductive states that remain stable over the course of 1000 seconds, demonstrating the non-volatile characteristics of the device.

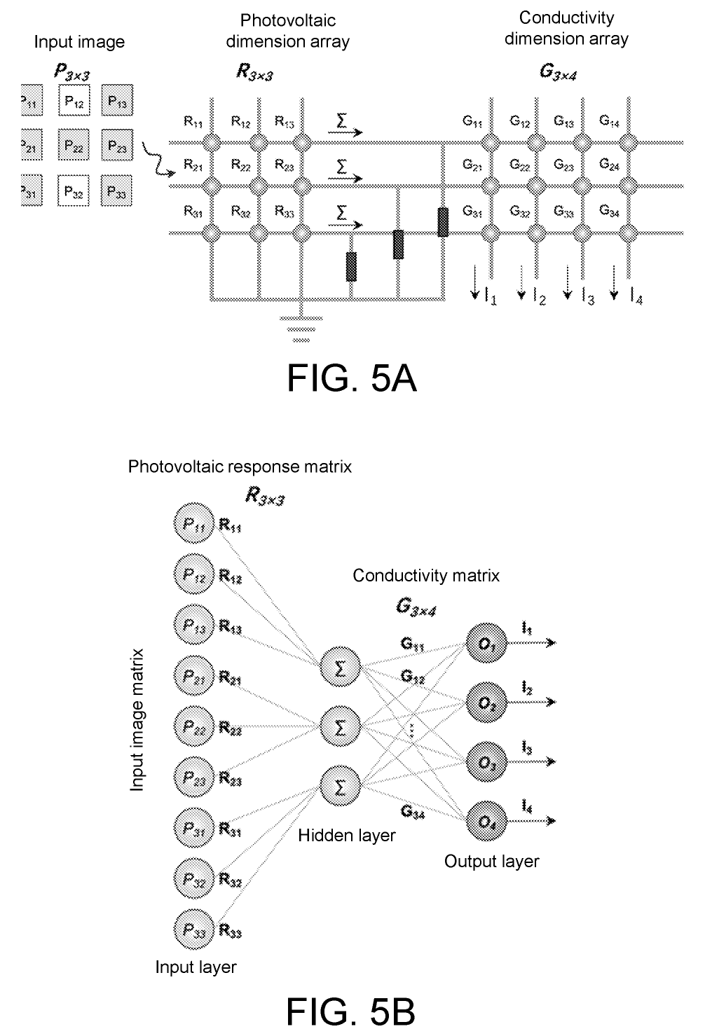

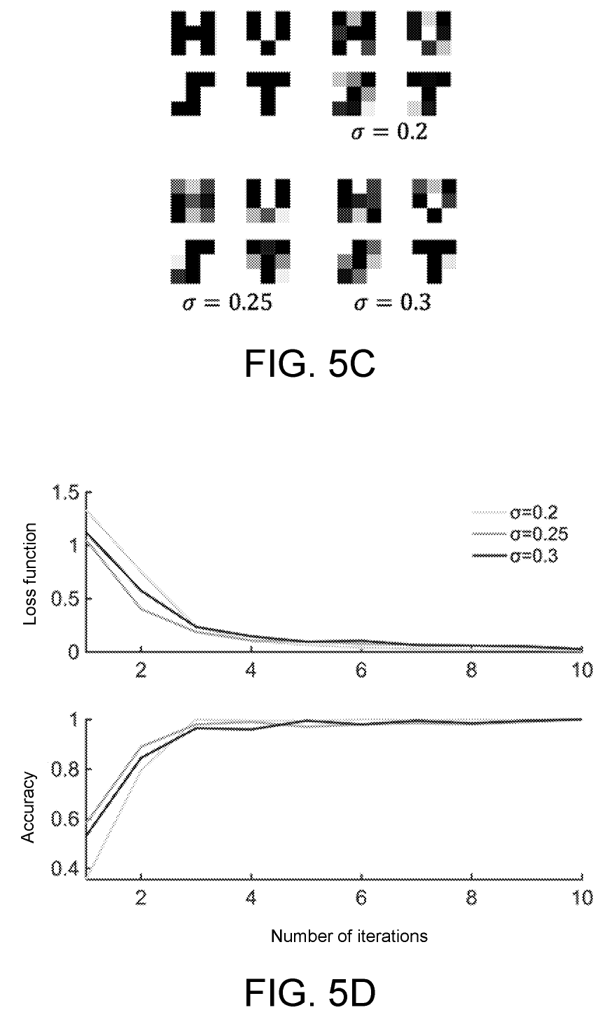

Based on the aforementioned dual-dimensional memory junction device, the embodiments of the present disclosure utilize the first contact electrode and the second contact electrode on the dual-dimensional memory junction device as the word lines and bit lines, respectively, to integrate into the crossbar array. FIG. 5A illustrates a circuit connection architecture of two crossbar arrays, wherein a resistance of the conductivity dimension array may be continuously adjusted to convert voltage signals into current signals. The embodiment shown in FIG. 5A depicts the Hadamard product of an input image matrix P_{3×3} with a photovoltaic dimension array R_{3×3}, where each image pixel corresponds to one dual-dimensional memory junction device of the photovoltaic dimension array, thereby outputting three current quantities. These three output currents are converted into voltage signals under a voltage division of a fixed resistor and are input into a subsequent conductivity dimension array G_{3×4}. Each device on the conductivity dimension array forms an element in a matrix, enabling matrix-vector multiplication operations through Kirchhoff's current law and Ohm's law, ultimately producing four outputs to complete a four-classification task. FIG. 5B is a computational graph of a network architecture corresponding to the circuit architecture. The embodiment employs online learning, wherein the weights of the two dimensions are updated in situ using a backpropagation algorithm. It should be noted that the network size in the system may be further expanded to process more complex image information.

FIG. 5C and FIG. 5D specifically illustrate the classification task for the letters 'H', 'U', 'S', and 'T'. In this context, 𝜎 represents the intensity of the random noise generated. It can be observed that as the random noise increases, the accuracy of the network in recognition remains stable, indicating that the system exhibits excellent robustness.

In conclusion, the present disclosure, when compared to the related art, possesses the following advantages.

The present disclosure provides the dual-dimensional memory junction device, including the first contact electrode, the doped n-type Si layer, the AgOₓ charge trapping layer, and the second contact electrode sequentially stacked from the bottom to top. The charge trapping layer, in combination with the doped n-type Si layer, forms the heterojunction transition region. In the AgOₓ charge trapping layer, where 0.4 < x < 1.2, the area of the charge trapping layer is greater than that of the second contact electrode for the purpose of photo-sensing. The present disclosure is capable of storing information in two distinct dimensions—photovoltaic and electrical conductivity—unlike existing devices which can only achieve single-dimensional memory functionality.

The present disclosure presents a method based on the dual-dimensional memory junction device. Leveraging the inherent self-rectifying characteristics of the device as a PN junction, the integration of the device into the crossbar array does not require additional gating devices. Moreover, the present disclosure features the theoretically minimal requirement of two terminals, which is advantageous for large-scale integration.

The present disclosure presents an application based on the dual-dimensional memory junction device, utilizing two dimensions of the device to construct a photovoltaic dimension array and a conductivity dimension array. The photovoltaic dimension array executes the Hadamard product of the optical matrix and the electrical matrix, outputting an electrical signal in vector form. The vector is then input into the conductivity dimension matrix to accomplish matrix-vector multiplication, thereby performing image information classification tasks. The dual-dimensional arrays constructed from a single device enable the development of a compact and efficient machine vision system.

It should be understood that expressions such as "comprising" and "may include," as used in the present disclosure, indicate the presence of disclosed functions, operations, or elements and do not preclude one or more additional functions, operations, and elements. In the present disclosure, terms such as "including" and/or "having" can be interpreted as specifying certain features, numbers, operations, elements, components, or combinations thereof, but should not be construed as excluding the possibility of the presence or addition of one or more other features, numbers, operations, elements, components, or combinations thereof.

Furthermore, in the present disclosure, the term "and/or" encompasses any and all combinations of the associated listed terms. For instance, the expression "A and/or B" may include A, may include B, or may include both A and B.

In the description of the embodiments of the present disclosure, it should be noted that, unless otherwise explicitly specified and defined, the term "connection" should be broadly construed. For instance, "connection" may refer to both detachable and non-detachable connections; "connection" may also refer to direct connections or indirect connections via an intermediary medium. Specifically, "fixed connection" implies that the entities are connected such that their relative positional relationship remains unchanged. "Rotational connection" indicates a connection allowing relative rotational movement, and "sliding connection" denotes a connection permitting relative sliding movement. The directional terms mentioned in the embodiments of the present disclosure, such as "top," "bottom," "inner," "outer," "left," "right," etc., are merely references to the directions in the accompanying drawings. Therefore, the use of directional terms is intended to facilitate a clearer and better understanding of the embodiments of the present disclosure, rather than to indicate or imply that the referenced devices or elements must possess a specific orientation, or be constructed and operated in a specific orientation, and thus should not be construed as limiting the embodiments of the present disclosure.

Furthermore, in the embodiments of the present disclosure, the mathematical concepts mentioned, such as symmetry, equality, parallelism, and perpendicularity, are defined in relation to the current level of technological development, rather than as strictly absolute definitions in the mathematical sense. A certain degree of deviation is permissible, allowing for approximate symmetry, approximate equality, approximate parallelism, and approximate perpendicularity. For instance, when A is described as parallel to B, it indicates that A and B are either parallel or approximately parallel, with the angle between A and B ranging from 0 degrees to 10 degrees. Similarly, when A is described as perpendicular to B, it indicates that A and B are either perpendicular or approximately perpendicular, with the angle between A and B ranging from 80 degrees to 100 degrees.

The aforementioned description represents merely specific embodiments of the present disclosure, and the scope to be protected by the present disclosure is not limited to these embodiments. Any variations or substitutions that may be readily conceived by those skilled in the pertinent field of technology, within the technical scope disclosed by the present disclosure, should be encompassed within the scope to be protected by the present disclosure. Therefore, the scope to be protected by the present disclosure shall be determined by the scope of the claims.

What is claimed is:

1. A dual-dimensional memory junction device, comprising a first contact electrode, a doped n-type Si layer, an AgOₓ charge trapping layer, and a second contact electrode stacked sequentially from bottom to top, wherein, 0.4<x<1.2;
wherein the doped n-type Si layer has a Fermi energy level lower than a bandgap midline energy level thereof, the AgOₓ charge trapping layer is combined with the doped n-type Si layer to form a heterojunction transition region, an area of the AgOₓ charge trapping layer is larger than an area of the second contact electrode;
the first contact electrode and the second contact electrode are provided for providing ohmic contact and voltage driving;
the heterojunction transition region is configured for trap ionization and deionization transitions based on the AgOₓ charge trapping layer, under voltage drive, continuous adjustability and mutual coupling of memory intensity are achieved in two dimensions of photovoltaic responsivity and electrical conductivity, with non-volatility.

2. The dual-dimensional memory junction device according to claim 1, wherein the first contact electrode is Al, Ti, Al silicide, or Ti silicide, and the second contact electrode is Au or Pt.

3. The dual-dimensional memory junction device according to claim 1, wherein a doping impurity in the doped n-type Si layer is a combination of one or more materials, the doped n-type Si layer is P-doped, and an order of magnitude of a doping concentration is 1E15cm⁻³.

4. The dual-dimensional memory junction device according to claim 1, wherein a thickness of the first contact electrode is 3nm-200nm, a thickness of the doped n-type Si layer is 30nm-500μm, a thickness of the AgOₓ charge trapping layer is 10nm-100nm, and a thickness of the second contact electrode is 3nm-200nm.

5. A performance acquisition method based on the dual-dimensional memory junction device according to claim 1, specifically:
after applying a negative voltage on the second contact electrode of the dual-dimensional memory junction device, a forward voltage is adopted to read a resistance state of the dual-dimensional memory junction device under unilluminated conditions, and an decrease of the resistance state of the dual-dimensional memory junction device is acquired; meanwhile, based on a 0V short-circuit state, a short-circuit current of the dual-dimensional memory junction device is read under illuminated conditions, and an increase of the photovoltaic responsivity of the dual-dimensional memory junction device is acquired;
after applying the forward voltage on the second contact electrode of the dual-dimensional memory junction device, the forward voltage is adopted to read the resistance state of the dual-dimensional memory junction device under the unilluminated conditions, and an increase of the resistance state of the dual-dimensional memory junction device is acquired; meanwhile, based on the 0V short-circuit state, the short-circuit current of the dual-dimensional memory junction device is read under the illuminated conditions, and a decrease of the photovoltaic responsivity of the dual-dimensional memory junction device is acquired.

6. The performance acquisition method based on the dual-dimensional memory junction device according to claim 5, wherein with an increase of the thickness of the AgOₓ charge trapping layer, an amplitude of the forward voltage adopted for reading the resistance state of the dual-dimensional memory junction device is also increased.

7. A neural network application method based on the dual-dimensional memory junction device according to claim 1, comprising the following steps:
the first contact electrode and the second contact electrode of the dual-dimensional memory junction device serve as word lines and bit lines respectively, thereby achieving integration in a crossbar array configuration;
one of the crossbar arrays is used as a photovoltaic response dimension array to map all pixels of an input optical image in array form in the photovoltaic response dimension array, so that a Hadamard product operation is performed between an optical image and a photovoltaic response matrix corresponding to the photovoltaic response dimension array, and a current vector is output;
another one of the crossbar arrays is used as a conductivity dimension array to convert the output current vector to a voltage vector for input to the conductivity dimension array, thereby completing a matrix-vector multiplication through Kirchhoff's current law and Ohm's law, and outputting a classification task of the optical image.

8. A preparation method based on the dual-dimensional memory junction device according to claim 1, comprising the following steps:
step 1: a doped n-type Si layer is prepared by doping a molten material during a growth of monocrystalline Si using a Czochralski method or a float zone method, or an intrinsic Si layer is grown using either the Czochralski method or the float zone method, and then the doped n-type Si layer is prepared through thermal diffusion doping or ion implantation methods;
step 2: at least one member selected from the group of sputtering, physical vapor deposition, and chemical vapor deposition is adopted to prepare the first contact electrode on a rear side of the doped n-type Si layer;
step 3: a masking layer for the AgOₓ charge trapping layer is prepared on the doped n-type Si layer through patterning, and then the AgOₓ charge trapping layer is prepared, subsequently, the masking layer is removed;
step 4: a patterned masking layer for the second contact electrode is prepared above the AgOₓ charge trapping layer, and then the second contact electrode is prepared, the masking layer is removed to complete the preparation of the dual-dimensional memory junction device.

9. The preparation method according to claim 8, wherein the preparation processes for the second contact electrode, the AgOₓ charge trapping layer, and the first contact electrode is one of the following: sputtering, physical vapor deposition, chemical vapor deposition, molecular beam epitaxy, atomic layer deposition, pulsed laser deposition, or electrochemical methods.
